(19) United States
(12) Patent Application Publication
(10) Pub. No.: US 2023/0062418 A1
(43) Pub. Date: Mar. 2, 2023

(54) SYSTEM AND METHOD FOR FEATURE SIGNAL ENHANCEMENT USING A SELECTIVELY BONDED PHOTOLUMINESCENT MATERIAL

(71) Applicant: KLA Corporation, Milpitas, CA (US)

(72) Inventors: Grace Hsiu-Ling Chen, Los Gatos, CA (US); Jinsang Kim, Ann Arbor, MI (US)

(21) Appl. No.: 17/887,078

(22) Filed: Aug. 12, 2022

Related U.S. Application Data
(60) Provisional application No. 63/303,519, filed on Jan. 27, 2022.
(60) Provisional application No. 63/238,778, filed on Aug. 31, 2021.

(51) Int. Cl. G01N 21/95; G01N 21/64; G01N 21/91

(52) U.S. Cl. CPC G01N 21/9501; G01N 21/643; G01N 21/91; G01N 2021/6439; G01N 2021/646

(57) ABSTRACT

A patterned wafer is disclosed, in accordance with one or more embodiments of the present disclosure. The patterned wafer may include at least a first material and at least a second material, where the first material may be different from the second material. The patterned wafer may further include a photoluminescent material configured to selectively bind to one of the first material or the second material to enhance a feature of interest.

### CROSS-REFERENCE TO RELATED APPLICATIONS

The present application claims the benefit under 35 U.S.C. § 119(e) of U.S. Provisional Patent Application Ser. No. 63/238,779, filed Aug. 31, 2021 and U.S. Provisional Patent Application Ser. No. 63/303,519, filed Jan. 27, 2022, both of which are incorporated herein by reference in the entirety.

### TECHNICAL FIELD

The present invention generally relates to defect detection and pattern measurements, and, more particularly, to a system and method for selectively enhancing a defect or pattern signal using a selectively bonded photoluminescent material.

### BACKGROUND

As the demand for integrated circuits having ever-small device features continues to increase, the need for improving defect detection mechanisms continues to grow. Current inspection systems rely on principles of light scattering for defect signal generation. However, one disadvantage of using light scattering principles is that defect signal generation is directly proportional to the size of the defect, where the defect signal decreases as the size of the defect shrinks.

Wafer noise induced by process variation increases node after node and is expected to continue to increase. The increase in wafer noise is due to at least three factors: (1) higher difficulties to manufacture shrunken design structure, (2) similar length scale of surface roughness, edge roughness, and edge placement error are expected to remain, and (3) noise scattering element packed more densely as design structure shrinks. This poses a great challenge for current inspection systems that rely on light scattering principles.

To keep up with the sensitivity demand, shorter wavelength inspection platforms are needed. However, development of future shorter wavelength development faces great challenges. For example, the development of light source and sustainable optics of the future shorter wavelength are insufficient to support inspection throughput demand and are too costly to support optical inspection cost target.

As such, it would be advantageous to provide system and method to remedy the shortcomings of the approaches identified above.

### SUMMARY

An inspection system is disclosed, in accordance with one or more embodiments of the present disclosure. The inspection system includes an illumination source configured to generate one or more illumination beams. The inspection system includes a substrate including at least a first material and at least a second material, where the first material is different from the second material. The substrate includes a photoluminescent material configured to selectively bind to one of the first material or the second material to enhance a feature of interest on the substrate. The inspection system includes a set of optical elements configured to direct the one or more illumination beams from the illumination source to a surface of the substrate. The inspection system includes one or more detectors configured to detect photoluminescent emission emitted by the photoluminescent material of one of the first material or the second material of the substrate. The set of optical elements are configured to direct the photoluminescent emission from the photoluminescent material of one of the first material or the second material of the substrate to the one or more detectors.

A patterned wafer is disclosed, in accordance with one or more embodiments of the present disclosure. The patterned wafer includes at least a first material and at least a second material, where the first material is different from the second material. The patterned wafer further includes a photoluminescent material configured to selectively bind to one of the first material or the second material to enhance a feature of interest.

A method is disclosed, in accordance with one or more embodiments of the present disclosure. The method includes generating one or more illumination beams using an illumination source. The method further includes directing the one or more illumination beams to a substrate using a set of optical elements. The substrate includes at least a first material and at least a second material, where the first material is different from the second material. The substrate further includes a photoluminescent material configured to selectively bind to one of the first material or the second material. The method further includes detecting photoluminescent emission emitted preferentially from the photoluminescent material of one of the first material or the second material of the substrate using one or more detectors.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a simplified schematic of an inspection system including a photoluminescent patterned substrate, in accordance with one or more embodiments of the present disclosure;

FIG. 2A illustrates a conceptual view of a patterned substrate, in accordance with one or more embodiments of the present disclosure;

FIG. 2B illustrates a conceptual view of a patterned substrate including a defect, in accordance with one or more embodiments of the present disclosure;

FIG. 2C illustrates a side conceptual view of a patterned substrate including a photoluminescent material selectively attached to a portion of the patterned substrate, in accordance with one or more embodiments of the present disclosure;

FIG. 3A illustrates a side conceptual view of a patterned substrate, in accordance with one or more embodiments of the present disclosure;

FIG. 3B illustrates an exploded conceptual view of a patterned substrate including one or more photoluminescent materials, in accordance with one or more embodiments of the present disclosure;

FIG. 4A illustrates a side conceptual view of a patterned substrate including a linker molecule and photoluminescent marker molecule, in accordance with one or more embodiments of the present disclosure;

FIG. 4B illustrates a side conceptual view of a patterned substrate including a linker molecule and photoluminescent marker molecule, in accordance with one or more embodiments of the present disclosure;

FIG. 5A illustrates a side conceptual view of a patterned substrate including a self-assembled monolayer linker molecule and photoluminescent marker molecule, in accordance with one or more embodiments of the present disclosure;

FIG. 5B illustrates a simplified schematic of method of selectively marking a patterned substrate using a self-assembled monolayer linker molecule and photoluminescent marker molecule, in accordance with one or more embodiments of the present disclosure; and

FIG. 6 illustrates a flow diagram depicting a method to detect one or more defects using the photoluminescent material, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a system and method for enhancing photon emission using a selectively bonded photoluminescent material. For example, the photoluminescent material may be configured to selectively attach to at least one of a first material or a second material of a substrate, such as those materials found on a patterned wafer. For instance, an illumination source may be configured to excite the photoluminescent material of the first material or the second material to cause the photoluminescent material to emit photoluminescent emission. In this regard, the photoluminescent material may be configured to preferentially attach to one of the first material or the second material to enhance the photon emission of a feature of interest (e.g., a defect of interest, a pattern of interest, or a material of interest) formed of at least one of the first material or the second material. As such, this preferential amplification may enhance the signal contrast. It is noted that the scattering signal may depend on a volume of the defect. Embodiments of the present disclosure may modify a surface of a substrate by selectively attaching a photoluminescent material to the surface of the substrate. A thin defect (e.g., a defect with a very shallow depth) may have the same amount of photoluminescent signal as a thick defect (e.g., a defect with a larger z-depth). The signal generation of the photoluminescent material of the present disclosure may be area dependent, rather than volume dependent. In this regard, the signal of the thin defect may be enhanced.

In some embodiments, the photoluminescent material may have a life time in the nanosecond scale. It is noted that a photoluminescent material with a life time on the nanosecond scale may be very efficient in generating photons. For example, a photoluminescent material with a life time of 10 nanoseconds may generate 10⁵ photons (in milliseconds scale). In this regard, photon generation may be much more efficient than optical scattering. Further it is noted that photoluminescent signal generation is typically higher than scatter signal generation. In this regard, the signal of the feature of interest (e.g., defect of interest, pattern of interest, or material of interest) is also enhanced compared to the scattered-based method.

In some embodiments, the one or more photoluminescent materials may include, but are not limited to, one or more organic dyes, one or more quantum dots, one or more carbon dots, one or more transition metals, or one or more conjugated polymers.

In some embodiments, the photoluminescent materials including a linker molecule and a marker molecule. For example, the linker molecule may include, but is not limited to, polydopamine, polynorepinephrine, or a self-assembled monolayer material and the marker molecule may include one or more hydrophobic fluorophores.

The system and method may be configured to reduce wafer noise. Further, the system and method may be configured to increase sensitivity enhancement without requiring additional instrument development and cost. Further, the system and method may be configured to allow optical inspection to detect defects of interest (DOI) for future design nodes.

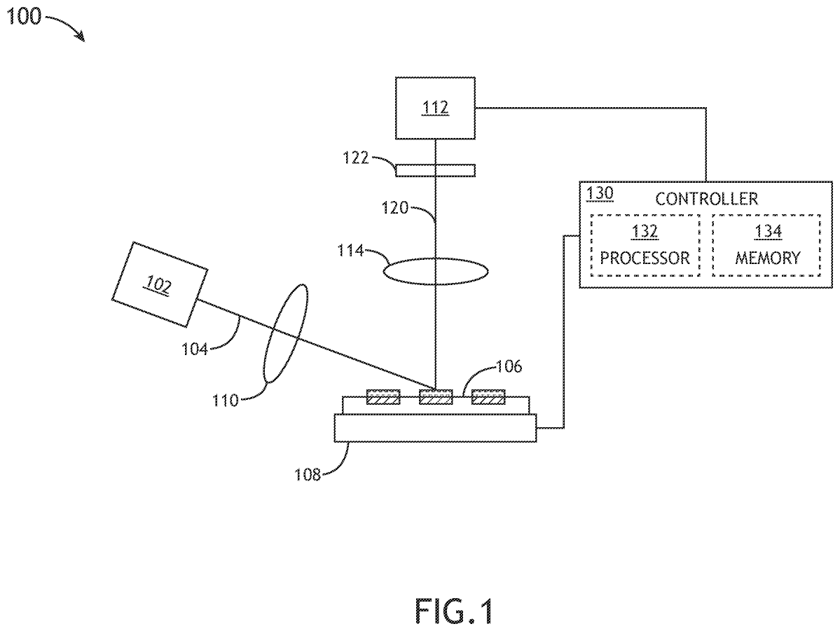

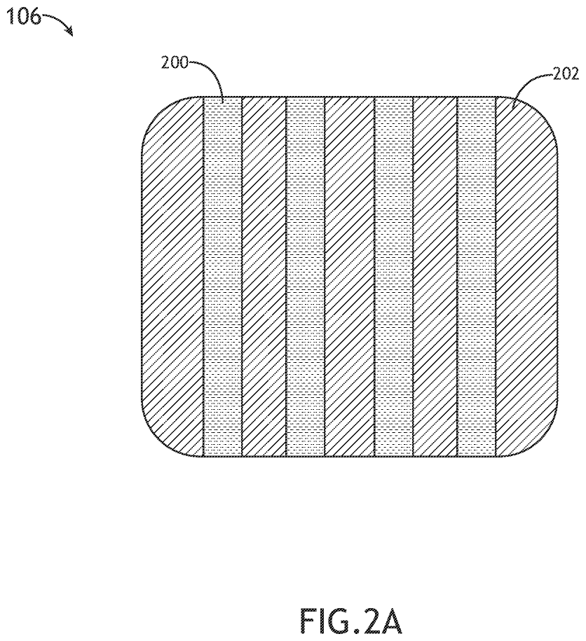

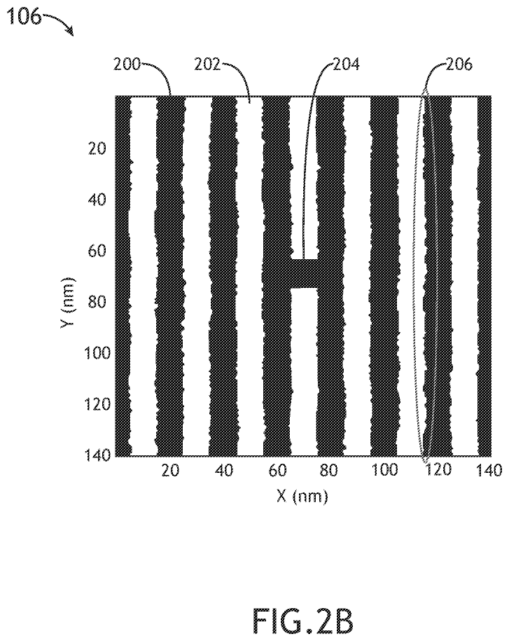

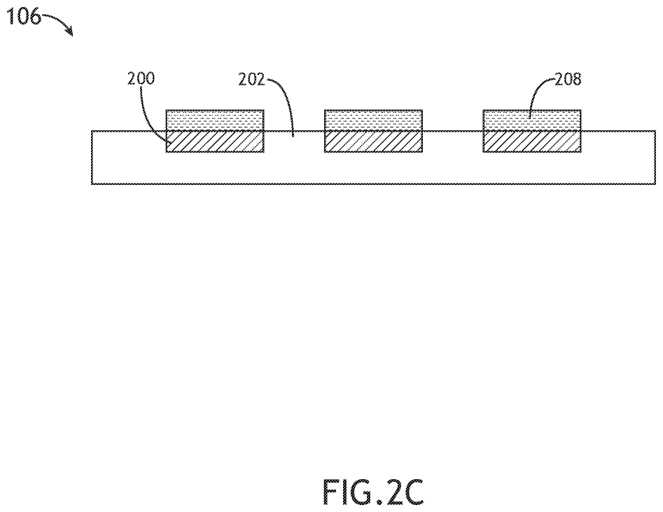

FIG. 1 is a simplified schematic diagram illustrating an inspection system 100, in accordance with one or more embodiments of the present disclosure. FIGS. 2A-2C are conceptual diagrams illustrating patterned substrates 106, in accordance with one or more embodiments of the present disclosure. It is noted herein that the patterned substrates 106 illustrated in FIGS. 2A-2C are shown at a high magnification for illustrative purposes.

In embodiments, the system 100 may include an illumination source 102 configured to generate one or more illuminations beams 104. The illumination source 102 may include any type of illumination source suitable for exciting a photoluminescent material on a surface of a substrate.

In embodiments, the illumination source 102 includes one or more narrowband illumination sources. For example, the illumination source 102 may include, but is not limited to, a laser system, including one or more laser sources, configured to generate a laser beam including illumination of a selected wavelength or range or wavelengths. The laser system may be configured to produce any type of laser radiation such as, but not limited to, infrared radiation, visible radiation, and/or ultraviolet (UV) radiation. By way of another example, the illumination source 102 may include, but is not limited to, one or more light emitting diodes (LEDs).

In embodiments, the illumination source 102 includes one or more broadband illumination sources. For example, the illumination source 102 may include, but is not limited to, a broadband lamp configured to generate broadband light of a range of wavelengths (e.g., white light). For instance, the illumination source 102 may include, but is not limited to, a broadband plasma (BBP) light.

In embodiments, the system includes one or more optical elements 110 configured to direct the illumination beam 104 to the substrate 106. For example, the one or more optical elements 110 may include one or more spectral filters configured to direct the optimal spectral light to the substrate 106. For instance, the one or more spectral filters may be configured to maximize excitation of the photoluminescent material (as discussed further herein).

In embodiments, the one or more optical elements 110 direct the beam 104 to the surface of the substrate 106 at a substantially fixed angle of incidence. In another embodiment, the one or more optical elopements 110 direct the beam 104 to the surface of the substrate 106 at a configurable angle of incidence.

In embodiments, the system 100 includes a stage assembly 108 suitable for securing and positioning the substrate 106. The stage assembly 108 may include any sample stage architecture known in the art. For example, the stage assembly 108 may include a linear stage. By way of another example, the stage assembly 108 may include a rotational stage.

It is noted herein that the inspection system 100 may operate in either an imaging mode or a non-imaging mode. In an imaging mode, individual objects (e.g., defects) are resolvable within the illuminated spot on the sample. In a non-imaging mode of operation, all of the light collected by one or more detectors is associated with the illuminated spot on the sample. It is further noted that both imaging and non-imaging modes may be applied within the scope of the present disclosure.

In embodiments, the system 100 includes one or more collection optics 114 configured to collect photoluminescent emission 120 emitted from the substrate 106 and direct the photoluminescent emission 120 to one or more detectors 112. It is noted herein that one or more collection optics 114 may be oriented in any position relative to the substrate 106. The one or more collection optics 114 may include an objective lens oriented normal to the substrate 106. The one or more collection optics 114 may further include a plurality of collection lenses oriented normal to photoluminescent emission 120 from multiple solid angles.

In embodiments, the one or more optical elements 122 are configured to condition the photoluminescent emission 120 prior to detection by the one or more detectors 112. The one or more optical elements 122 may include any elements known in the art suitable for conditioning the photoluminescent emission 120 including, but not limited to, one or more diffractive elements, one or more refractive elements, one or more beam splitters, one or more polarizers, one or more wavelength-selective filters, or one or more neutral density filters.

In embodiments, the one or more optical elements 122 include one or more wavelength-selective filters suitable for passing fluorescent emission corresponding to the emission spectra of one or more photoluminescent materials while blocking wavelengths associated with the illumination beam 104. The one or more optical elements 122 may further separate photoluminescent illumination from one or more distinct emission spectra associated with one or more photoluminescent materials such that each distinct emission spectra is directed to a separate detector 112. In embodiments, the one or more optical elements 122 may include a diffraction grating configured to physically separate wavelengths associated with the illumination beam 104 from one or more wavelengths associated with the emission spectra of one or more photoluminescent materials. Further, it is noted herein that the detector 112 may include any optical detector known in the art suitable for measuring light emerging from the substrate 106. For example, the detector 112 may include, but is not limited to, a CCD detector, a TDI detector, a photomultiplier tube (PMT), an avalanche photodiode (APD), or the like.

It is noted herein that the one or more optical elements 110 and the one or more collection optics 114 may be referred to as a single set of optical elements. It is further noted that the one or more optical elements 110 and the one or more collection optics 114 may share common optical elements. For example, a single objective lens may be configured to both direct illumination to the sample and collect returned light from the sample.

In embodiments, the system 100 includes a controller 130 communicatively coupled to the one or more detectors 112. The controller 130 may include one or more processors 132 configured to execute a set of program instructions maintained in a memory medium 134 (memory 134).

In embodiments, the one or more processors 132 are configured to execute program instructions configured to direct the one or more processors 132 to identify one of more defects 204 on the substrate 106 based on the collected photoluminescent emission 120. For example, the one or more processors 132 may be configured to generate a defect map of the surface of the substrate 106 including one or more identified defects 204. In embodiments, the controller 130 is further communicatively coupled to the stage assembly 108 to associate photoluminescent emission 120 with specific locations on the sample associated with one or more defects 204.

Referring to FIGS. 2A-2C, in embodiments, the substrate 106 may include a patterned substrate 106. For example, the substrate 106 may include a patterned wafer 106. For instance, the substrate 106 may include an integrated circuit (IC) device 106.

The pattern of the substrate 106 may be formed of at least a first material 200, and a second material 202, where the first material 200 is different from the second material 202. For example, as shown in FIGS. 2A-2B, the substrate 106 may include a grating pattern formed from the interlacing of the first material 200 and the second material 202.

Although FIGS. 2A-2C depict the patterned substrate 106 being formed of a first material 200 and a second material 202, it is noted that the patterned substrate 106 may be formed of any number of materials. For example, the patterned substrate 106 may be formed of at least a first material, a second material, a third material . . . up to an Nth number of materials.

In embodiments, the first material or the second material may include, but is not required to include, porous carbon doped organosilicon (pSiCOH), copper (Cu), cobalt (Co), ruthenium (Ru), tungsten (W), aluminum (Al), silicon (Si), polycrystalline silicon, titanium nitride (TiN), silicon nitride (Si3N4), and the like.

Referring to FIG. 2B, the substrate 106 may include a defect 204 positioned between a portion of the first material 200 and a portion of the second material 202. For example, the substrate 106 may include a bridge defect positioned between a portion of the first material 200 and a portion of the second material 202. For instance, the bridge defect may be a 10 nm bridge defect, where the critical dimension of the line and space array is 10 nm. Further, the substrate 106 may include edge noise 206 caused by line edge roughness and edge placement error (approximately 1-2 nm noise level for both).

The substrate 106 may include one or more photoluminescent materials 208 configured to selectively bind to one of the first material 200 or the second material 202 to enhance a feature of interest on the substrate 106. For example, the one or more photoluminescent materials 208 may be configured to preferentially attach to a targeted material (e.g., the first material 200 or the second material 202) to enable the targeted material to have enhanced photon emission based on the properties of the photoluminescent material 208. In one instance, the one or more photoluminescent materials 208 may be configured to preferentially attach to the first material 200 and not the second material 202, such that only the signal from the first material 200 is enhanced. In another instance, the one or more photoluminescent materials 208 may be configured to preferentially attach to the second material 202 and not the first material 200, such that only the signal from the second material 202 is enhanced.

For purposes of the present disclosure, it is noted that a feature of interest may include, but is not limited to, a defect of interest, a pattern of interest, or a material of interest. For example, the one or more photoluminescent materials 208 may be configured to selectively bind to one of the first material 200 or the second material 202 to enhance a defect of interest. By way of another example, the one or more photoluminescent materials 208 may be configured to selectively bind to one of the first material 200 or the second material 202 to enhance a pattern of interest. By way of another example, the one or more photoluminescent materials 208 may be configured to selectively bind to one of the first material 200 or the second material 202 to enhance a material of interest.

In some embodiments, the photoluminescent material 208 may have a photoluminescent emission time scale less than or equal to 10 nanoseconds (ns). For example, the photoluminescent material 208 may have a photoluminescent emission time scale between 2 ns and 10 ns. In this regard, the signal of the photoluminescent material 208 may be substantially enhanced. It is noted herein that the photoluminescent material may emit significantly more photons than photon generation through scattering, as discussed previously herein. For example, in a non-limiting example, a fluorophore with a lifetime of 10 ns can generate 10⁵ photons in 1 millisecond (ms), which is much higher than traditional light interaction via scattering. As such, the signal may be enhanced.

In some embodiments, the photoluminescent material 208 may have a spatial characteristic length between 2 nanometers and 4 nanometers (nm). For example, in a non-limiting example, the edge noise due to the line roughness and edge displacement may be approximately 1-2 nm, such that the spatial characteristic length of 2-4 nm may serve as a spatial filter to reduce the sensitivity to the presence of edge roughness and edge placement error. In this regard, the edge roughness and edge placement error may be selectively desensitized, thereby reducing noise.

In some embodiments, the photoluminescent material 208 may be configured to selectively bind at the surface level of one of the first material or the second material. In this regard, the noise from the stack and previous layers may be minimized.

In some embodiments, the photoluminescent material 208 may have a quantum yield greater than 15 percent. For example, the photon conversion between the absorbed light (for photoluminescence excitation) and emission light may have a quantum yield of 40 percent.

In some embodiments, the size of the photoluminescent molecule 208 may be between 2 nm and 4 nm. For example, the size of the photoluminescent molecule 208 may be 3 nm.

The one or more photoluminescent materials 208 may include one or more photoluminescent molecules including, but not limited to, one or more organic dyes (e.g., Cy5, Cy3, rhodamine, or the like), one or more quantum dots (e.g., cadmium telluride (CdTe) dots, cadmium sulfide (CdS) dots, zinc sulfide (ZnS) dots, or the like), one or more carbon dots, one or more transition metals, or one or more conjugated polymers (e.g., polypyrrole, polythiophene, or the like).

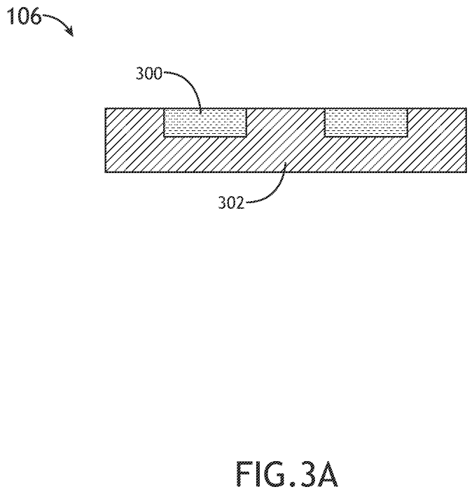

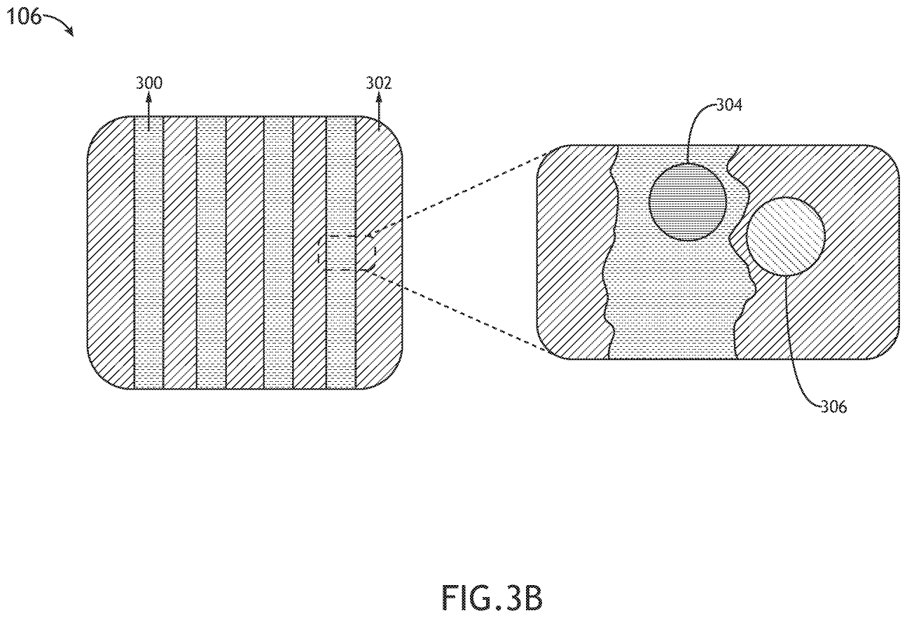

Referring to FIGS. 3A-3B, in some embodiments, the photoluminescent material 208 may include a hydrophobic fluorophore (e.g., Cy5). For example, the first material 200 may include a low k dielectric material 302 (e.g., porous organosilicon) and the second material 202 may include a metal 300 (e.g., Cu, W, Co, Ru, Al, and the like). For instance, the hydrophobic fluorophore 304 (e.g., Cy5) may be configured to fluorescently label the low k dielectric material 302 (e.g., porous organosilicon). In this regard, the hydrophobic fluorophore 304 (e.g., Cy5) may be configured to preferentially attach to a hydrophobic surface such as a low k dielectric surface, such that selectivity is achieved. It is noted that hydrophobic fluorophores, such as Cy5, may be configured to selectively tether to the low-k dielectric surface (e.g., as shown in FIG. 3) and produce bright fluorescence emission while no emission may be observed from the metal patterns due to metal-induced fluorescent quenching. For example, it is noted that the hydrophobic fluorophore may incidentally attach 306 to the hydrophilic metal surface 300, however, the metal surface will not fluoresce due to metal-induced fluorescent quenching.

In some embodiments, the photoluminescent material 208 includes a linker molecule and a marker molecule. The linker molecule may be configured to enable a preferential material connection between the substrate and the marker molecule, where the marker molecule may be configured to selectively mark a targeted material to enable amplification of a feature of interest signal (e.g., defect of interest, pattern of interest, or material of interest). The linker molecule may include, but is not required to include, one of polydopamine (pDA), polynorepinephrine (pNE), self-assembled monolayer (SAM), or the like. In this embodiment, the selectivity may be controlled by the linker material.

It is noted herein that the linker molecule may be used to functionally and/or physically separate the photoluminescent molecule from the material of the substrate to maximize the efficiency of the photoluminescent properties of the photoluminescent molecule. The length of the linker molecule may be adjusted to balance the physical separation of a luminescent molecule from other molecules that may induce quenching of the photoluminescent output.

A photoluminescent marker (or photoluminescent molecule) in an inspection system 100 may include any type of photoluminescent particle suitable for generating photoluminescence. For example, the one or more photoluminescent tags may include one or more fluorescent tags. For instance, the signal molecule may include one or more hydrophobic fluorophores, one or more hydrophilic fluorophores, and the like. It is noted that the description of fluorescence in the present disclosure is intended to be illustrative rather than limiting and that detection of defects using any type of photoluminescent material is within the scope of the present disclosure.

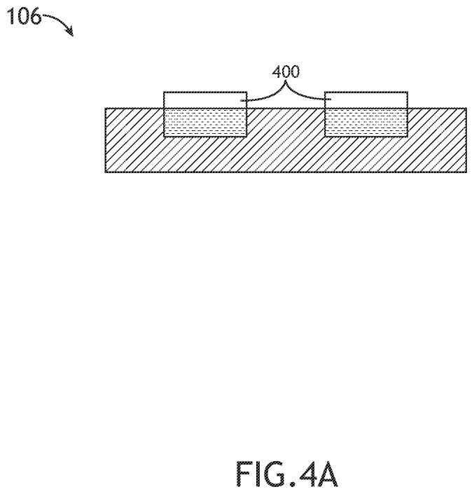

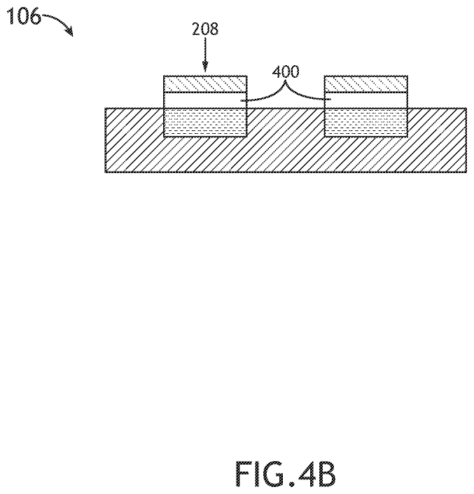

Referring to FIGS. 4A-4B, in a non-limiting example, the linker molecule 400 may include one of pDA or pNE. For example, one of the first material 200 or the second material 202 may be coated with one of pDA or pNE. For instance, the first material 200 may include a metal material, where the metal material may be coated with one of pDA or pNE. In some embodiments, one or more fluorophores may be incorporated into the coating. For example, the one or more fluorophores may be co-polymerized with pDA or pNE to selectively mark the metal structure. In alternative embodiments, the one or more fluorophores may be configured to selectively attach to the pDA or pNE surface after the metal surface is coated.

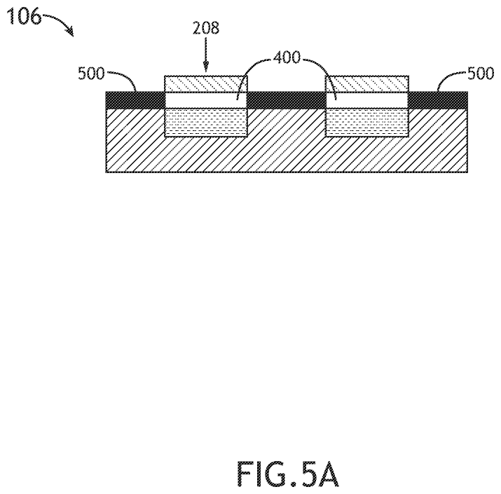

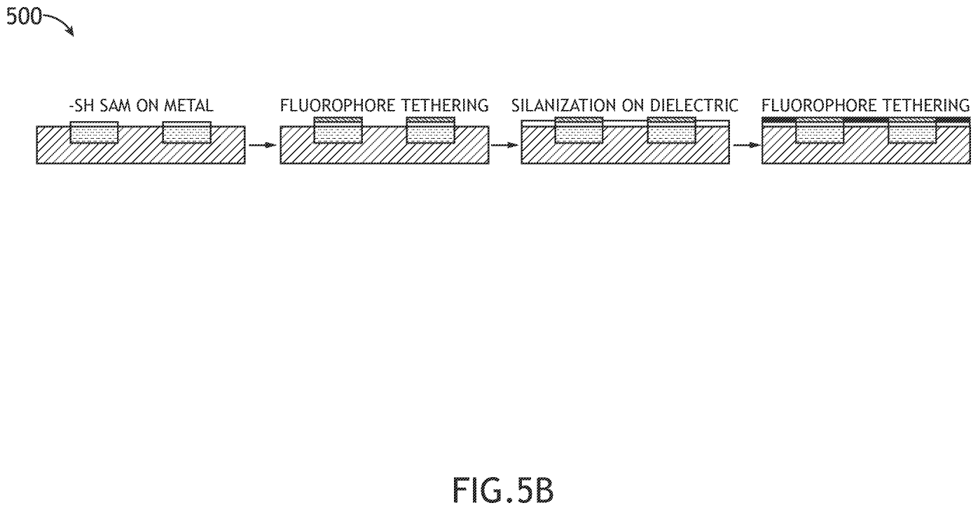

Referring to FIGS. 5A-5B, in some embodiments, the linker molecule 400 may include a SAM 500. For example, the first material 200 may include a low dielectric constant material and the second material 202 may include a metal, where surface modification of the low dielectric constant material via hydrolysis followed by silanization with addition of trichloro-alkyl silane compounds or other similar substances (such as trimethoxy-silane, triethoxy-silane) may form SAM 500 on the low dielectric material. Selective marking of the metal may be achieved by tethering one or more fluorophores on thiol-like molecules or phosphonate molecules on metals with one or more additional fluorophores on the SAM 500.

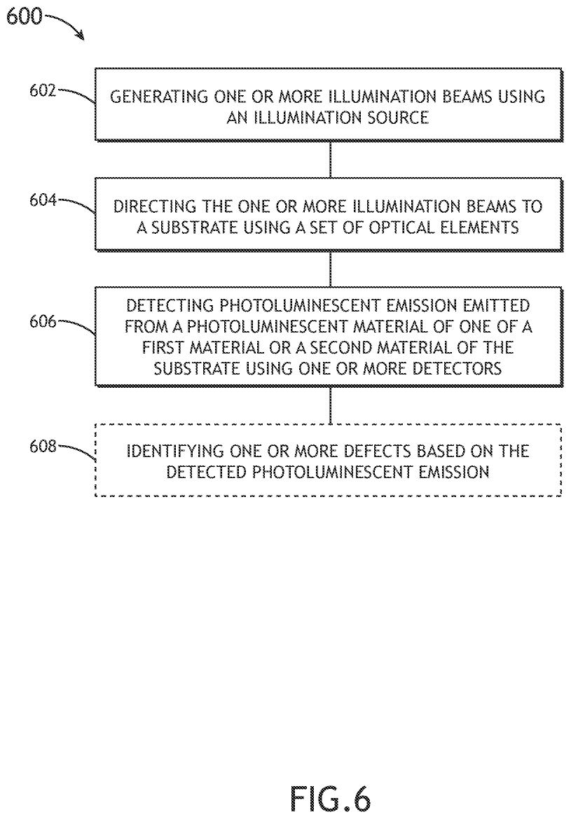

FIG. 6 illustrates a flow diagram depicting a method 600 to detect defects using photoluminescent materials selectively attached to a target material of the substrate, in accordance with one or more embodiments of the present disclosure.

In a step 602, one or more illumination beams may be generated. For example, the illumination source 102 may be configured to generate one or more illumination beams 104. In some embodiments, the illumination source 102 may be configured to excite the photoluminescent material 208 on one of the first material 200 or the second material 202.

In a step 604, the one or more illumination beams may be directed to the substrate. For example, the set of optical elements 110 may be configured to direct the one or more illumination beams 104 to the substrate 106. For example, the illumination beams 104 may be directed to the substrate 106 to excite the photoluminescent material 208 on one of the first material 200 or the second material 202. In this regard, photoluminescent light may be emitted by the one or more photoluminescent materials 208 of one of the first material 200 or the second material 202 of the substrate 106 in response to the illumination beams 104.

In a step 606, the emitted photoluminescent light may be detected. For example, the one or more detectors 112 may be configured to detect the photoluminescent emission 120 from the photoluminescent material 208.

In a step 608, one or more defects may be identified based on the detected photoluminescent emission. For example, the one or more defects 204 may be identified by generating a defect map of the surface of the substrate 106 on which the one or more identified defects 204 are identified.

Although embodiments of the present disclosure are directed to an inspection system, it is contemplated that the patterned wafer including the selectively bounded photoluminescent material may be used with any characterization system including, but not limited to, an optical metrology system (e.g., image-based metrology system), or the like.

It is further contemplated that each of the embodiments of the method described above may include any other step(s) of any other method(s) described herein. In addition, each of the embodiments of the method described above may be performed by any of the systems described herein.

Referring again to FIG. 1, the one or more processors 132 of the controller 130 may include any processing element known in the art. In this sense, the one or more processors 132 may include any microprocessor-type device configured to execute algorithms and/or instructions. In one embodiment, the one or more processors 132 may consist of a desktop computer, mainframe computer system, workstation, image computer, parallel processor, or any other computer system (e.g., networked computer) configured to execute a program configured to operate the system 100, as described throughout the present disclosure. It is further recognized that the term “processor” may be broadly defined to encompass any device having one or more processing elements, which execute program instructions from a non-transitory memory medium 134. Therefore, the above description should not be interpreted as a limitation on the present invention but merely an illustration.

The memory medium 134 may include any storage medium known in the art suitable for storing program instructions executable by the associated one or more processors 132. By way of a non-limiting example, the memory medium 134 may include a non-transitory memory medium. By way of additional non-limiting examples, the memory medium 134 may include, but is not limited to, a read-only memory, a random access memory, a magnetic or optical memory device (e.g., disk), a magnetic tape, a solid state drive, and the like. It is further noted that memory 134 may be housed in a common controller housing with the one or more processors 134. In an alternative embodiment, the memory 134 may be located remotely with respect to the physical location of the one or more processors 132 and controller 130. For instance, the one or more processors 132 of the controller 130 may access a remote memory (e.g., server), accessible through a network (e.g., internet, intranet, and the like).

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include, but not be limited to, systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include, but not be limited to, systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An inspection system, the inspection system comprising:
an illumination source configured to generate one or more illumination beams;
a substrate, the substrate including at least a first material and at least a second material, wherein the first material is different from the second material, the substrate including a photoluminescent material configured to selectively bind to one of the first material or the second material to enhance a feature of interest on the substrate;
a set of optical elements configured to direct the one or more illumination beams from the illumination source to a surface of the substrate; and
one or more detectors configured to detect photoluminescent emission emitted by the photoluminescent material of one of the first material or the second material of the substrate, the set of optical elements configured to direct the photoluminescent emission from the photoluminescent material of one of the first material or the second material of the substrate to the one or more detectors.

2. The inspection system of claim 1, wherein the photoluminescent material preferentially attaches to one of the first material or the second material of the substrate.

3. The inspection system of claim 1, wherein the illumination source is configured to excite the photoluminescent material of one of the first material or the second material of the substrate.

4. The inspection system of claim 1, wherein the photoluminescent material includes at least one of:
one or more organic dyes, one or more fluorophores, one or more quantum dots, one or more carbon dots, one or more transition metals, one or more conjugated polymers, or one or more phosphorescent nanoparticles.

5. The inspection system of claim 1, wherein the photoluminescent material further includes a linker molecule.

6. The inspection system of claim 4, wherein the photoluminescent material is configured to selectively bind to a monolayer of one of the first material or the second material of the substrate.

7. The inspection system of claim 4, wherein the photoluminescent material has a photoluminescent emission time scale less than 10 nanoseconds.

8. The inspection system of claim 4, wherein the photoluminescent material has a spatial characteristic length between 2 nanometers and 4 nanometers.

9. The inspection system of claim 4, wherein the photoluminescent material has a quantum yield greater than 15 percent.

10. The inspection system of claim 5, wherein the photoluminescent material includes at least one of:
one or more hydrophobic fluorophores or one or more hydrophilic fluorophores.

11. The inspection system of claim 10, wherein the linker molecule includes a self-assembled monolayer material.

12. The inspection system of claim 1, wherein one of the first material or the second material includes at least one of:
porous carbon doped organosilicon, copper, cobalt, ruthenium, tungsten, aluminum, silicon, polycrystalline silicon, titanium nitride, or silicon nitride.

13. The inspection system of claim 1, wherein the size of the photoluminescent material is between 3 nanometers and 5 nanometers.

14. The inspection system of claim 1, further comprising:
a controller communicatively coupled to the one or more detectors, the controller including one or more processors to execute program instructions causing the one or more processors to identify one or more defects on the surface of the substrate based on the detected photoluminescent emission from the one or more detectors.

15. The inspection system of claim 14, wherein the feature of interest includes a defect of interest.

16. The inspection system of claim 14, wherein the feature of interest includes a pattern of interest.

17. The inspection system of claim 14, wherein the feature of interest includes a material of interest.

18. The inspection system of claim 14, wherein the substrate includes a wafer.

19. A patterned wafer, the patterned wafer comprising:
a first material;
a second material, wherein the first material is different from the second material; and
a photoluminescent material configured to selectively bind to one of the first material or the second material to enhance a feature of interest.

20. The patterned wafer of claim 19, wherein the photoluminescent material preferentially attaches to one of the first material or the second material of the patterned wafer.

21. The patterned wafer of claim 19, wherein the photoluminescent material includes at least one of:
one or more organic dyes, one or more quantum dots, one or more carbon dots, one or more transition metals, or one or more conjugated polymers.

22. The patterned wafer of claim 19, wherein the photoluminescent material further includes a linker molecule.

23. The patterned wafer of claim 21, wherein the photoluminescent material is configured to selectively bind to a monolayer of one of the first material or the second material of the patterned wafer.

24. The patterned wafer of claim 21, wherein the photoluminescent material has a photoluminescence emission time scale less than 10 nanoseconds.

25. The patterned wafer of claim 21, wherein the photoluminescent material has a spatial characteristic length between 2 nanometers and 4 nanometers.

26. The patterned wafer of claim 21, wherein the photoluminescent material has a quantum yield greater than 15 percent.

27. The patterned wafer of claim 22, wherein the photoluminescent materials includes at least one of:
one or more hydrophobic fluorophores or one or more hydrophilic fluorophores.

28. The patterned wafer of claim 27, wherein the linker molecule includes a self-assembled monolayer material.

29. The patterned wafer of claim 19, wherein one of the first material or the second material includes at least one of:
porous carbon doped organosilicon, cooper, cobalt, ruthenium, tungsten, aluminum, silicon, polycrystalline silicon, titanium nitride, or silicon nitride.

30. The patterned wafer of claim 19, wherein the patterned wafer includes an integrated circuit device.

31. The patterned wafer of claim 19, wherein the feature of interest includes a defect of interest.

32. The patterned wafer of claim 19, wherein the feature of interest includes a pattern of interest.

33. The patterned wafer of claim 19, wherein the feature of interest includes a material of interest.

34. A method, the method comprising:
generating one or more illumination beams using an illumination source;
directing the one or more illumination beams to a substrate using a set of optical elements, the substrate including at least a first material and at least a second material, wherein the first material is different from the second material, the substrate further including a photoluminescent material configured to selectively bind to one of the first material or the second material; and
detecting photoluminescent emission emitted preferentially from the photoluminescent material of one of the first material or the second material of the substrate using one or more detectors.

35. The method of claim 34, further comprising:
identifying one or more defects on a surface of the substrate based on the detected photoluminescent emission from the one or more detectors.

36. The method of claim 34, wherein the photoluminescent material includes at least one of:
one or more organic dyes, one or more quantum dots, one or more carbon dots, one or more transition metals, or one or more conjugated polymers.

37. The method of claim 34, wherein the photoluminescent material further includes a linker molecule.

38. The method of claim 36, wherein the photoluminescent material is configured to selectively bind to a monolayer of one of the first material or the second material of the patterned substrate.

39. The method of claim 36, wherein the photoluminescent material has a photoluminescence emission time scale less than 10 nanoseconds.

40. The method of claim 36, wherein the photoluminescent material has a spatial characteristic length between 2 nanometers and 4 nanometers.

41. The method of claim 36, wherein the photoluminescent material has a quantum yield greater than 15 percent.

42. The method of claim 37, wherein the photoluminescent material includes at least one of:
one or more hydrophilic fluorophores or one or more hydrophobic fluorophores.

43. The method of claim 42, wherein the linker molecule includes a self-assembled monolayer material.

44. The method of claim 34, wherein one of the first material or the second material includes at least one of:
porous carbon doped organosilicon, cooper, cobalt, ruthenium, tungsten, aluminum, silicon, polycrystalline silicon, titanium nitride, or silicon nitride.
